(19) United States
(12) Patent Application Publication
(10) Pub. No.: US 2012/0229973 A1
(43) Pub. Date: Sep. 13, 2012

(54) TABLET PERSONAL COMPUTER

(76) Inventor: Shao-Chieh TING, Banchiau City (TW)

(21) Appl. No.: 13/043,184

(22) Filed: Mar. 8, 2011

(51) Int. Cl. H05K 7/00

(52) U.S. Cl. 361/679.56

(57) ABSTRACT

The present invention discloses a tablet personal computer, two sides of which are provided with interface slots including for charging, audio and other connection with external equipment. When being used, the tablet personal computer can be put vertically or horizontally on a dock on a desktop, which improves an existing trouble that interface wires and an audio wire must be used and increases safety and aesthetics while using the tablet personal computer.

### BACKGROUND OF THE INVENTION

a) Field of the Invention

The present invention relates to a tablet personal computer, and more particularly to a tablet personal computer which is able to be put vertically or horizontally on a dock on a desktop to increase safety and aesthetics while being used.

b) Description of the Prior Art

As development of technologies, a tablet personal computer must be smaller and lighter that it can be carried by a user conveniently. However, when the size of a tablet personal computer becomes smaller, there will be a certain limitation to related slots on that tablet personal computer.

For many tablet personal computers shown up in an existing market, only a single side of the computer is provided with interface slots. As the tablet personal computer is provided with a stronger operability, the user can put the tablet personal computer vertically or horizontally on the dock depending on his or her preference. However, due to uniqueness of the interface slots, when the user is using the tablet personal computer, the tablet personal computer can be only put vertically. On the other hand, when the tablet personal computer is used horizontally to watch a movie, an interface wire and an audio wire must be used to connect with external equipment such as a sound box. Therefore, the transmission wires are exposed in air, thereby affecting the safety and the aesthetics.

Referring to FIG. 7, it shows a three-dimensional view of a conventional tablet personal computer 11 which is put horizontally on a sliding base. When the conventional tablet personal computer is connected with external equipment, it should be connected through interface transmission wires 80, 90 and as the transmission wires are suspended in air, the safety and the aesthetics are affected.

Accordingly, to solve the aforementioned issues, a tablet personal computer is created by the present inventor.

### SUMMARY OF THE INVENTION

The primary object of the present invention is to provide a tablet personal computer on which is provided with two interface slots, allowing that the tablet personal computer can be put on a dock vertically or horizontally without suspending transmission wires for external equipment in air to affect the safety and the aesthetics.

To enable a further understanding of the said objectives and the technological methods of the invention herein, the brief description of the drawings below is followed by the detailed description of the preferred embodiments.

### BRIEF DESCRIPTION OF THE DRAWINGS

FIG. 1 shows a three-dimensional schematic view of the present invention.

FIG. 2 shows another three-dimensional schematic view of the present invention.

FIG. 3 shows a three-dimensional exploded view of the present invention and a dock.

FIG. 4 shows a three-dimensional schematic view of the present invention which is put vertically on the dock.

FIG. 5 shows a three-dimensional schematic view of the present invention which is put horizontally on the dock.

FIG. 6 shows a three-dimensional schematic view of the present invention or a conventional tablet personal computer which is put vertically on an external keyboard.

FIG. 7 shows a three-dimensional schematic view of the conventional tablet personal computer which is put horizontally on a sliding base.

### DETAILED DESCRIPTION OF THE PREFERRED EMBODIMENTS

The present invention is a tablet personal computer, including an e-book.

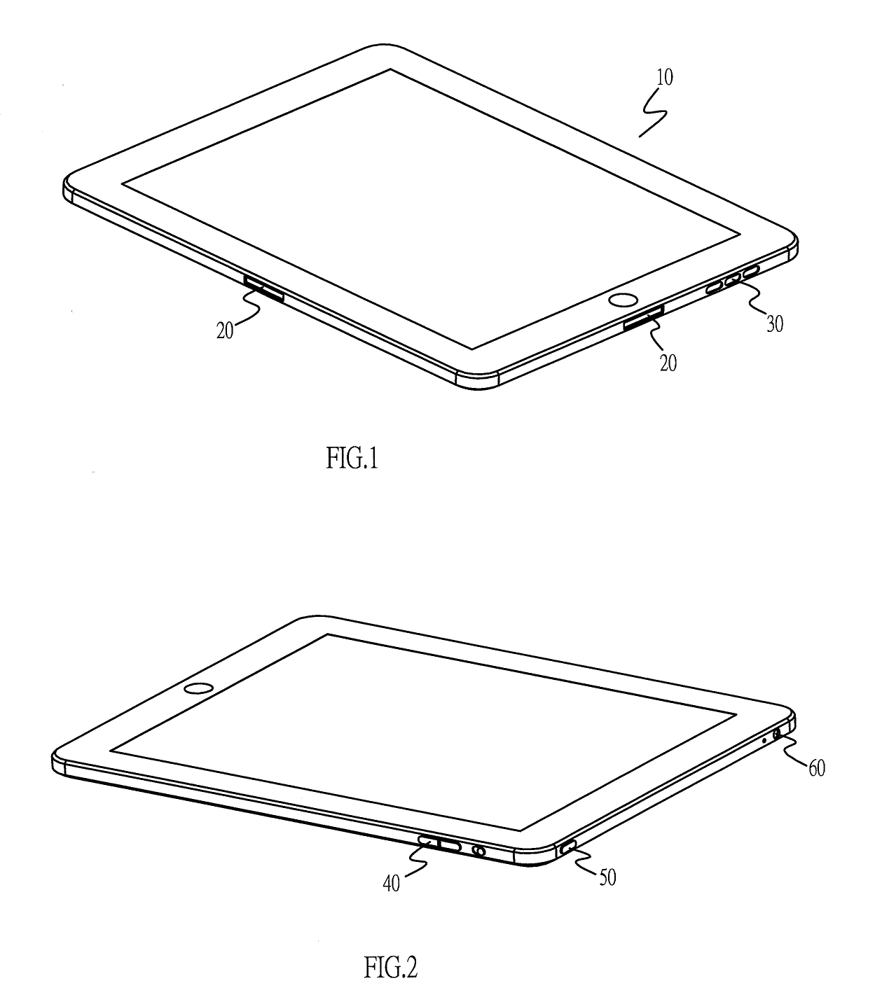

Referring to FIG. 1 and FIG. 2, it shows three-dimensional schematic views of the present invention. As shown in the drawings, the tablet personal computer or e-book 10 is provided with primary function keys and interface slots 20, including two interface slots 20, one of which is at a bottom and the other one is at a side of the tablet personal computer 10; a speaker hole 30; a volume control key 40; a power key 50; and an audio slot 60.

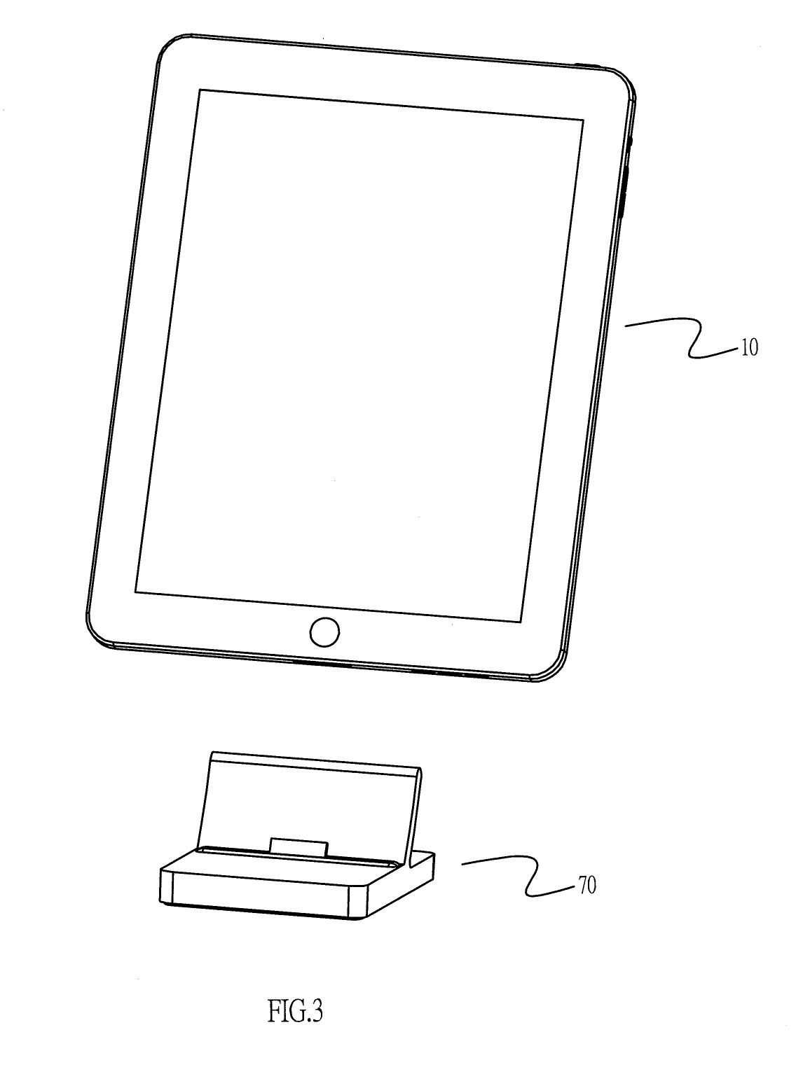

Referring to FIG. 3, it shows an exploded view of the tablet personal computer or e-book 10 and a dock 70 of the present invention, which are in use.

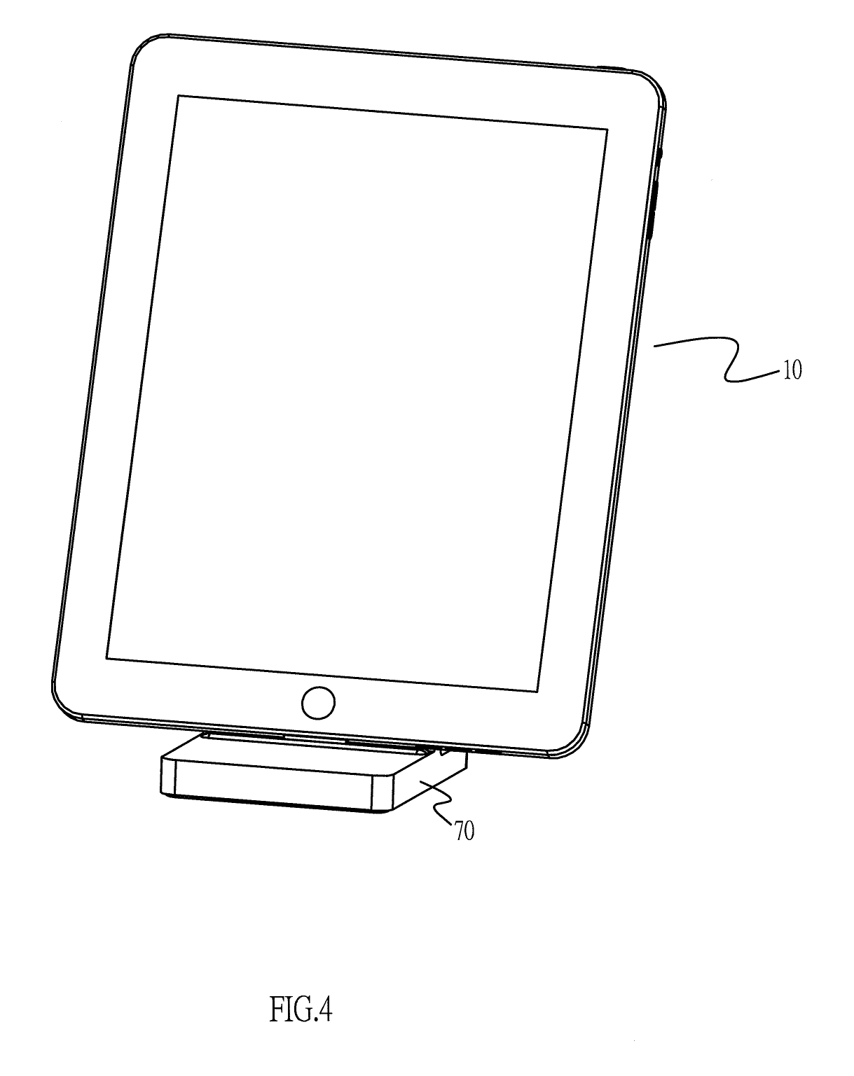

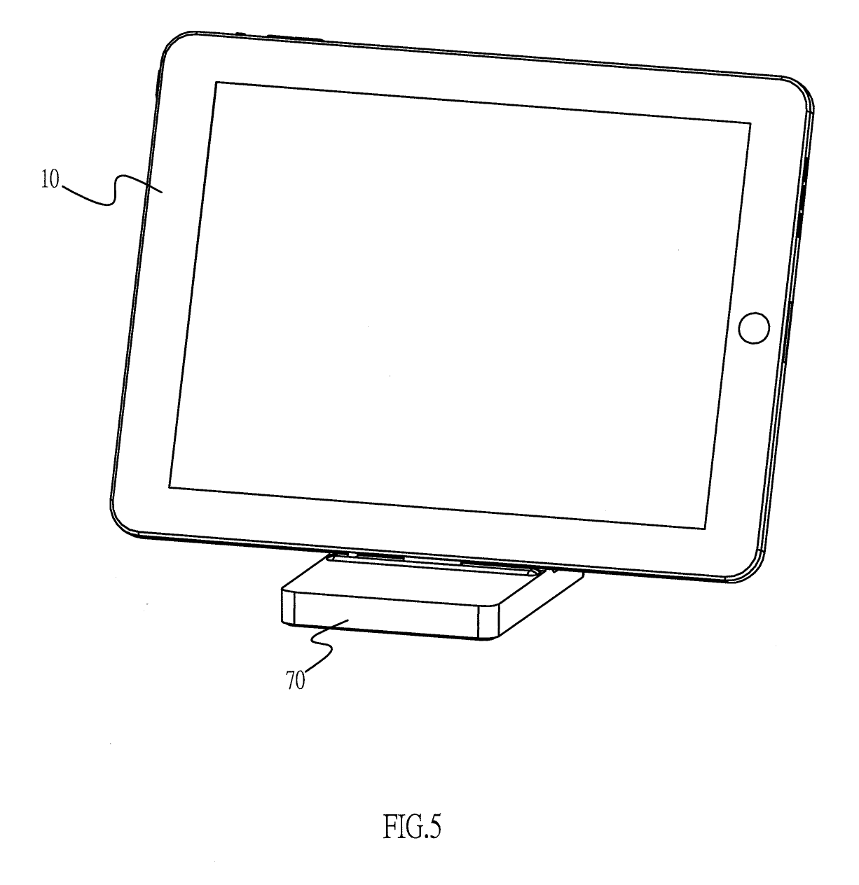

Referring to FIG. 4, it shows a three-dimensional schematic view of the tablet personal computer or e-book 10 of the present invention, which is put vertically on the dock 70, wherein through interface slots provided on the dock 70 and connection with interface transmission wires, a purpose of connecting with external equipment is achieved.

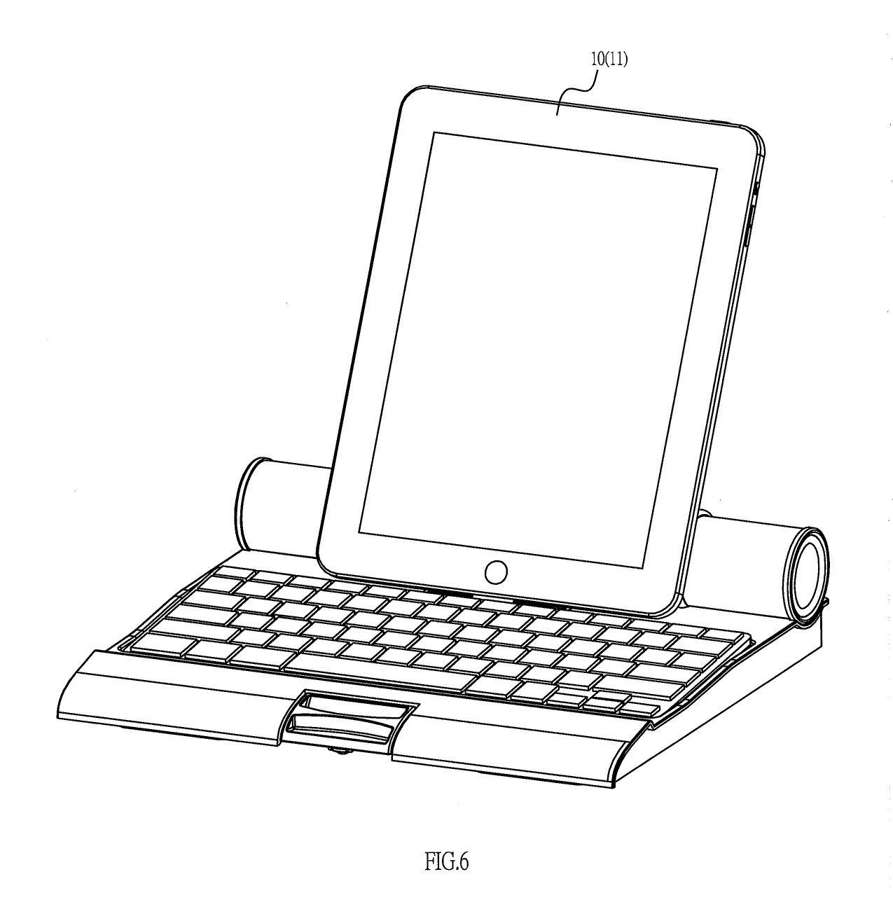

Referring to FIG. 5, it shows a three-dimensional schematic view of the tablet personal computer or e-book 10 of the present invention, which is put horizontally on the dock 70.

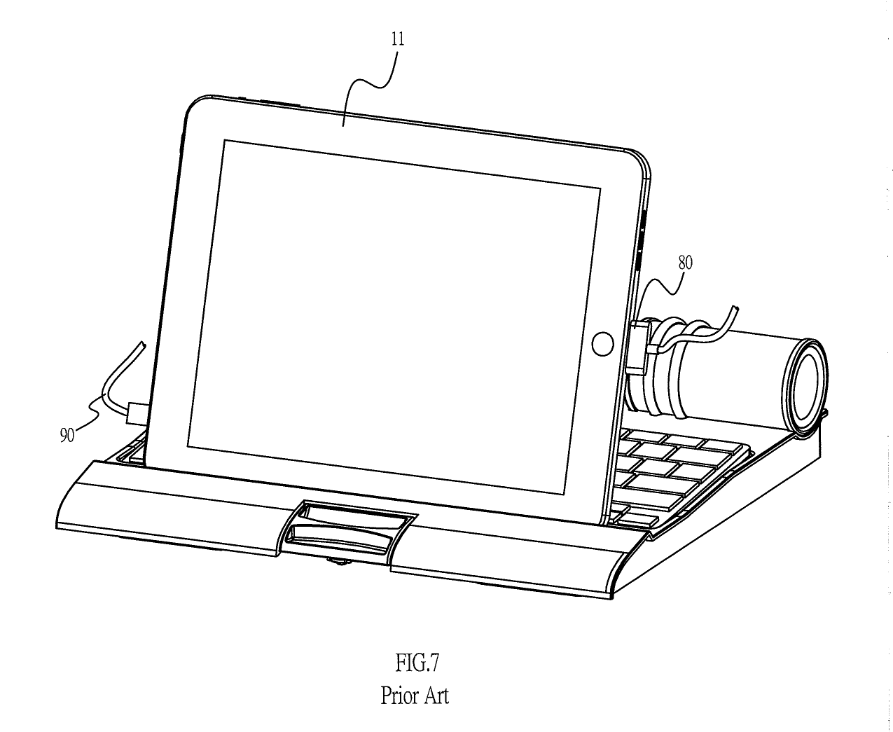

Referring to FIG. 6, it shows a three-dimensional schematic view of the tablet personal computer or e-book 10 of the present invention, or the conventional tablet personal computer 11, which is put on an external keyboard and a sliding base.

It is of course to be understood that the embodiments described herein is merely illustrative of the principles of the invention and that a wide variety of modifications thereto may be effected by persons skilled in the art without departing from the spirit and scope of the invention as set forth in the following claims.

What is claimed is:

1. A tablet personal computer, including an e-book, comprising following function keys and slots:
two interface slots which are provided respectively at a bottom and a side of the tablet personal computer to connect with external equipment;
a plurality of speaker holes which are provided at a side of the tablet personal computer;
a volume control key which is provided at a side of the tablet personal computer;
a power key which is provided at a side of the tablet personal computer; and
an audio slot which is provided at a side of the tablet personal computer.

2. The tablet personal computer according to claim 1, wherein the tablet personal computer is vertically or horizontally put on a dock.

3. The tablet personal computer according to claim 1, wherein through providing interface slots and interface transmission wires on the dock, the tablet personal computer is connected with external equipment.

4. The tablet personal computer according to claim 2, wherein through providing interface slots and interface transmission wires on the dock, the tablet personal computer is connected with external equipment.
